(19) United States
(12) Patent Application Publication
(10) Pub. No.: US 2004/0262265 A1
(43) Pub. Date: Dec. 30, 2004

(54) Wet processing apparatus, wet processing method and manufacturing method of semiconductor device

(75) Inventors: Michimasa Funabashi, Hachioji (JP); Masakatsu Kuwabara, Hitachinaka (JP); Kazunori Nemoto, Akishima (JP); Hiroyuki Mima, Hitachinaka (JP); Norio Suzuki, Mito (JP)

Correspondence Address: Stanley P. Fisher, Reed Smith, Suite 1400, 3110 Fairview Park Drive, Falls Church, VA, 22042-0681, US

(73) Assignee: Trecenti Technologies, Inc.

(21) Appl. No.: 10/875,826

(22) Filed: Jun. 25, 2004

(30) Foreign Application Priority Data
Jun. 26, 2003 (JP) P2003-182123

(51) Int. Cl. C23F 1/00; B44C 1/22; C03C 15/00; H01L 31/0232

(52) U.S. Cl. 216/83; 438/689; 438/745

(57) ABSTRACT

A manufacturing method of semiconductor device capable of suppressing or preventing formation of a dissolution region of composition atoms such as a pit in a semiconductor wafer. After oxide film on a semiconductor wafer is removed by dipping plural pieces of the semiconductor wafer accommodated in a carrier into chemical liquid containing fluoro acid, chemical liquid adhering to the semiconductor wafer is washed out of the semiconductor wafer by rinse processing using de-ionized water. At least in the rinse processing of this wet processing, light is projected to the semiconductor wafer from a light source provided on a wet etching apparatus. Adjusting electromotive force caused by battery reaction at a pn junction of the semiconductor wafer by adjusting the state of the light L enables generation of a pit in the semiconductor wafer.

### CROSS-REFERENCE TO RELATED APPLICATION

The present application claims priority from Japanese Patent Application No. JP 2003-182123 filed on Jun. 26, 2003, the content of which is hereby incorporated by reference into this application.

### TECHNICAL FIELD OF THE INVENTION

The present invention relates to a wet processing apparatus, a wet processing method and manufacturing method of semiconductor device and more particularly to a technology which is effectively applicable for wet processing such as wet etching processing and rinse processing performed on a semiconductor wafer.

### BACKGROUND OF THE INVENTION

The wet etching is classified into two types, namely, dip type and spin type. According to the dip method, the etching processing is carried out with a semiconductor wafer dipped within chemical liquid stored in an etching bath. On the other hand, according to the spin method, the etching processing is carried out by spraying chemical liquid onto the semiconductor wafer fixed on a supporting base. In any case, chemical liquid adhering to the surface of the semiconductor wafer is removed by rinsing after the etching processing finished. According to an example, “Seok-Woo Lee; Ihl Hyun Cho; Sang Hyuk Park; Hong Goo Choi; Nam Gawk Kim; Jong-Kwan Kim; Sang Beom Han; Kyung Ho Lee; VLSI and CAD, 1999. ICVC ′99. 6th International Conference on 26-27 Oct. 1999, pp. 249-252” describes the following technology that, in step for forming gate insulation films having a different thickness on the main surface of the semiconductor wafer, oxide film formed in a region in which a relatively thin gate oxide film is formed is removed after a relatively thick gate insulation film is formed.

### SUMMARY OF THE INVENTION

According to a first finding of the present inventors of the present invention, when the rinse processing is executed after the wet etching processing in order to expose the surface of the semiconductor wafer, silicone (Si) dissolves partially from the surface of the semiconductor, so that a pit or roughness is formed due to the dissolution.

An object of the present invention is to provide a technology capable of suppressing or preventing formation of any dissolution region of composition atoms such as the pit in the semiconductor wafer.

The aforementioned and other objects and novel features of the present invention will be apparent from a description of this specification and accompanying drawings.

Of the present invention disclosed in this specification, typical embodiments thereof are outlined as follows.

Namely, according to the present invention, the state of light irradiating to the semiconductor wafer is changed corresponding to a semiconductor wafer subjected to wet processing at the time of the wet processing.

Further the present invention provides a wet processing apparatus comprising a wet processing section for performing the wet processing onto the semiconductor wafer and a light source for adjusting the state of light irradiating to the semiconductor wafer at the time of the wet processing.

### BRIEF DESCRIPTIONS OF THE DRAWINGS

FIG. 1 is a plan view of the principal part of a semiconductor wafer after the wet processing which the present inventors considered;

FIG. 2 is a sectional view taken along the line X1-X1 in FIG. 1;

FIG. 3 is a sectional view of the principal part of the semiconductor wafer indicating a result of experiment executed to estimate the cause for the pit;

FIG. 4 is a sectional view of the principal part of the semiconductor wafer indicating other result of the experiment executed to estimate the cause for the pit;

FIG. 5 is an explanatory diagram of a chemical reaction when the pit is generated;

FIG. 6 is an explanatory diagram of energy band of a semiconductor substrate and oxidation reducing potential of rinse fluid when the pit is generated in FIG. 5;

FIG. 7 is a graph showing the relation between a difference in potential (voltage) between the semiconductor substrate and rinse fluid and a flowing current;

FIG. 8 is an explanatory diagram of chemical reaction when oxide film is deposited;

FIG. 9 is an explanatory diagram of an example of the wet processing apparatus according to an embodiment of the present invention;

FIG. 10 is a sectional view of major portion in manufacturing step of the semiconductor device according to an embodiment of the present invention;

FIG. 11 is a sectional view of the principal part in manufacturing step of the semiconductor device continued from FIG. 10;

FIG. 12 is a sectional view of the principal part in manufacturing step of the semiconductor device continued from FIG. 11;

FIG. 13 is a sectional view of the principal part in manufacturing step of the semiconductor device continued from FIG. 12;

FIG. 14 is a sectional view of the principal part in manufacturing step of the semiconductor device continued from FIG. 13; and

FIG. 15 is a sectional view of the principal part in manufacturing step of the semiconductor device continued from FIG. 14.

### DESCRIPTION OF THE PREFERRED EMBODIMENTS

Although the present invention will be described about plural sections or embodiments when required for convenience, those sections and embodiments are not unrelated to each other and one of them is a modification of part or all of the other one, detail, supplement or the like. When referring to the quantity of elements (including number, value, amount, range and the like) in the following embodiments, the present invention is not restricted to a particular quantity except that particularly a specific number is indicated or the number is limited principally to a particular one and thus, the number may be over or below the specific one. Further, needless to say, composition elements (including element steps) of the following embodiments are not always indispensable except that those are indicated particularly explicitly or clearly indispensable principally. When referring to the shape, position, relation and the like of the composition elements in the following embodiments, they include the ones substantially similar or identical to those factors except when particularly indicated or they are not theoretically. This is the same for the aforementioned numerals and range. Further, like reference numerals are attached to elements having the same function in all diagrams for explaining the embodiments and description thereof is omitted. In this embodiment, the MIS FET which is a field effect transistor is abbreviated as MIS and a p-channel type MIS is abbreviated as pMIS and a n-channel type MIS is abbreviated as NMIS. In the meantime, metal oxide semiconductor field effect transistor (MOS FET) is regarded as a lower level concept of the MIS.

Hereinafter, the embodiment of the present invention will be described in detail with reference to the accompanying drawings.

First, the object which the present inventors found out will be described. Prior to formation of a gate insulation film on the main surface (device formation face) of the semiconductor wafer (hereinafter referred to as wafer), an insulation film on the main surface of the wafer was removed by wet etching processing using chemical fluid containing hydrofluoric acid (HF) and after that, with the wafer main surface exposed, rinse processing using de-ionized water was executed to remove the aforementioned chemical fluid. As a result, the following problem occurs that a pit or roughness due to dissolution of silicone (hereinafter referred to as pit and the like) is generated in an active region of the wafer main surface.

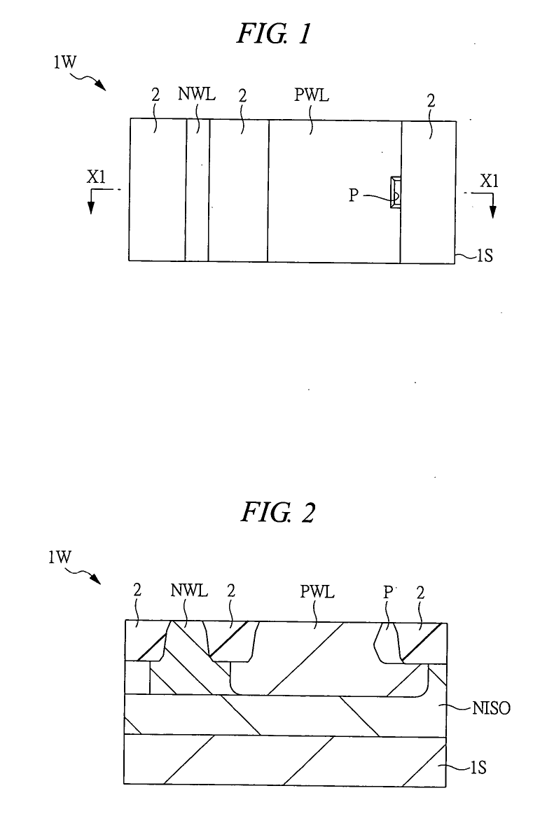

FIGS. 1, 2 show an example of the state of the pit P. FIG. 1 is a plan view of the principal part of a wafer 1W and FIG. 2 is a sectional view taken along the line X1-X1 of FIG. 2. A semiconductor substrate (hereinafter referred to as substrate) 1S constituting the wafer 1W is composed of, for example, p-type silicon (Si) mono-crystal and n-type embedding region NISO is formed in part thereof. In this n-type embedding region NISO, p-type well PWL and n-type well NWL are formed. In the main surface (device forming face) of this substrate 1S, for example, a groove-shaped separating portion 2 called shallow trench isolation (STI) is formed and at this stage, the n-type well NWL and p-type well PWL are exposed in the active region surrounded by that separating portion 2. The aforementioned pit P is a region formed because silicone (Si) in the well PWL elutes partially and in this example, the pit P is generated in an area in contact with the side face of the separating portion 2.

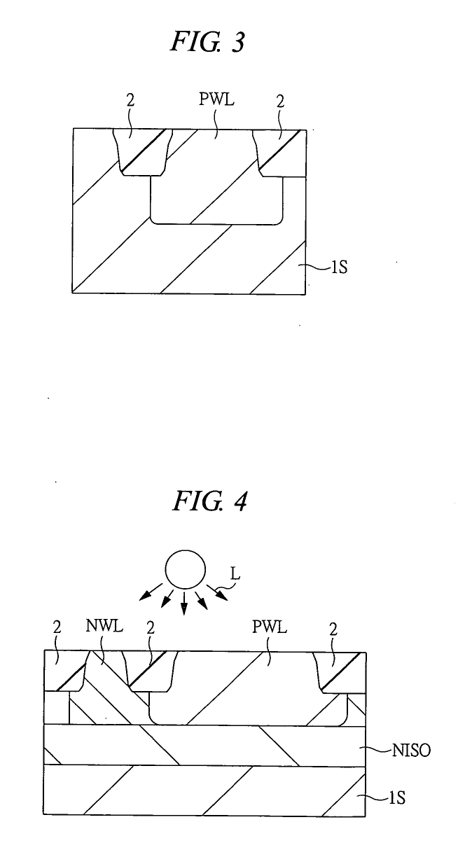

FIGS. 3, 4 show a sectional view of the principal part in the wafer 1W indicating an example of the result of an experiment conducted by the present inventors in order to find out the cause for occurrence of the aforementioned pit P. FIG. 3 shows a result of experiment conducted when no pn junction exists in the wafer 1W (substrate 1S). In this case, no pit P is generated. FIG. 4 shows a result of experiment conducted by increasing the intensity of light L to be irradiated on the wafer 1W and in this case also, the aforementioned pit P is not generated. On the other hand, when the intensity of light is insufficient at the time of rinse processing, the pit P is generated as shown in FIGS. 1, 2. In the experiment conducted by the present inventors, the pit P was generated under about 100 lux although no specific value can be mentioned because the threshold of the light intensity which generates the pit changes depending on the situation of the substrate 1S and no pit was generated under about 200 lux or higher. As a result of the various experiments, the present inventors have found that when the pn junction exists in the substrate 1S, an electromotive force is generated in the pn junction portion due to cell reaction depending on the intensity of light irradiated on the substrate 1S mainly at the time of the rinse processing, so that chemical reaction occurs on the main surface of the substrate 1S depending on a difference in its potential thereby silicone eluting to lead to the generation of the pit P or roughness.

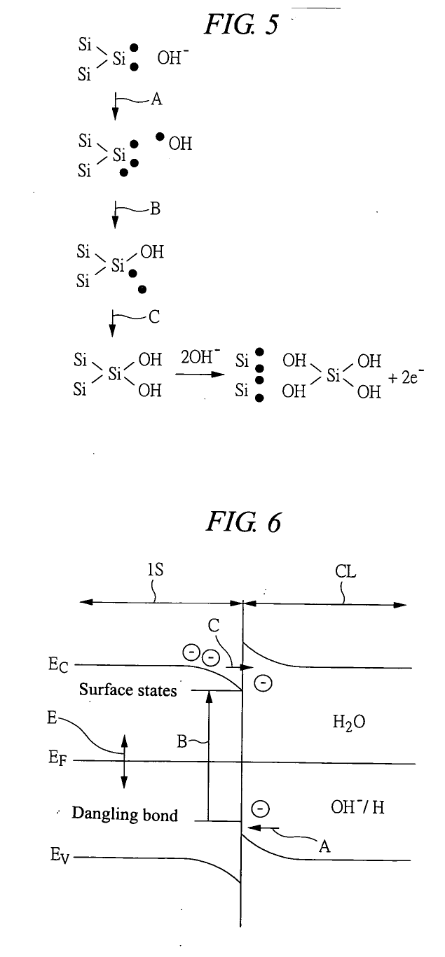

FIG. 5 shows a chemical reaction when the aforementioned pit P is generated. FIG. 6 shows an energy band of the substrate 1S when the pit is generated and the state of the oxidation reducing potential of cleaning liquid CL. A-C in FIG. 5 correspond to A-C in FIG. 6. E_{V} in FIG. 6 indicates valence band, E_{F} indicates Fermi level and E_{C} indicates a conductor. Assume that the exposed surface of the substrate 1S subjected to wet etching processing is in unstable condition having dangling bond. When the main surface of the substrate 1S is rinsed according to the rinse processing using de-ionized water or the like with this condition, electrons of hydroxyl group ion (OH⁻) are attracted by a difference in potential between the well NWL and the well PWL (A in FIGS. 5, 6). As a result, the hydroxyl group in that unstable condition bonds with silicone on the surface of the well PWL through covalent bond (B, C in FIGS. 5, 6).

When such a reaction is accelerated further, silicone in the substrate 1S elutes. Therefore, the state of the reaction (speed and the like) on the exposed surface of the substrate 1S can be adjusted by controlling a potential E at the pn junction of the substrate 1S. That is, the potential E at the pn junction portion of the substrate 1S can be controlled by adjusting the intensity or frequency of light irradiated to the substrate 1S during the aforementioned rinse processing, so that the state (speed and the like) of the reaction on the exposed surface of the well PWL can be adjusted.

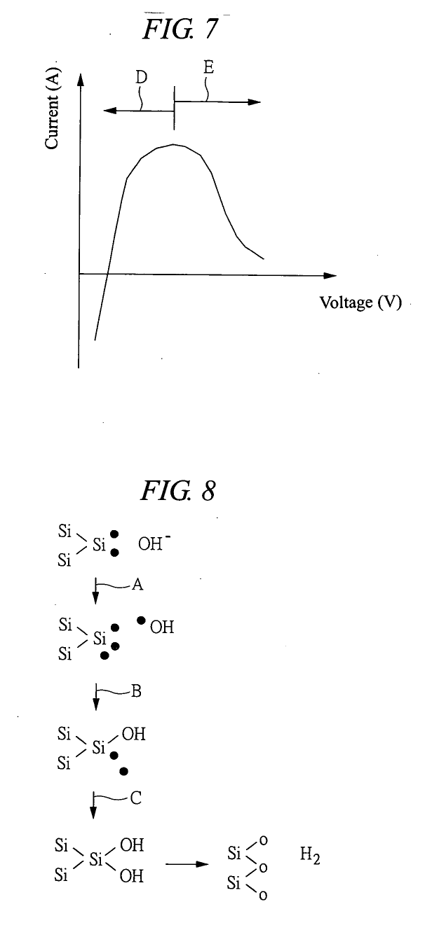

FIG. 7 shows the relation between a difference in potential (voltage) between the substrate 1S and cleaning liquid and flowing current. This Figure indicates that the dissolution amount of p-type silicone increases as the quantity of flowing current is higher. Even in a dark condition, a difference in potential corresponding to the concentration of impurity is generated when the pn junction exists. Although the dissolution amount of silicone increases as the voltage rises as shown in the same Figure, it decreases since some point as a border. Assuming that a left side with respect to that boundary is a dissolution region D while a right side is a passivation region E, in order to suppress the generation of the aforementioned pit P, the state of reaction on the exposed surface of the substrate 1S should be turned into a state in which the reaction occurs in the passivation region E as quickly as possible.

According to a first method of this embodiment, when the aforementioned pit P or the like occurs, by adjusting the state of light irradiating to the wafer 1W in terms of its intensity or wavelength at least at the time of rinsing processing for wet processing, of the wet etching processing and the rinse processing mentioned above, the difference in potential between the substrate 1 and chemical fluid or cleaning liquid is controlled for silicone in the substrate 1S not to elute into the chemical fluid or cleaning liquid, or to accelerate oxidation. As a specific example thereof, the wet processing is carried out while irradiating the wafer 1W with light of an intensity of about 200 lux or higher. Consequently, the generation of the pit P or the like can be suppressed or prevented. Thus, the yield and reliability of the semiconductor device can be improved. Further, because the yield of the semiconductor device can be improved, cost of the semiconductor device can be reduced.

Further, the present inventors first have found out that a following problem occurs when the first method simply applies to all actual production steps of the semiconductor device. That is, when light is irradiated on the wafer 1W during rinse processing in any case of the same wet etching processing and rinse processing as above in an actual production steps of the semiconductor device, the deficiency occurs conversely. That deficiency is that oxidation of the exposed surface of the substrate 1S is accelerated by the difference in potential between the well PWL and well NWL so that oxide film is formed. FIG. 8 shows a chemical reaction of the oxidation. A-C are the same as described above. In this case, hydroxyl groups bonding with adjoining silicones through covalent bond with each other to turn to water (H₂O), leaving the well PWL, while oxygen (O) remains bonding with silicone on the exposed surface of the substrate 1S. As a specific example the oxide films are deposited, it is possible to mention such a wet processing in which after forming a contact hole allowing both the P-type semiconductor region and the n-type semiconductor region to be exposed on the insulation film by executing the wet etching processing onto the wafer 1W where the insulation films are deposited, the rinse processing with cleaning liquid such as de-ionized water is carried out. If oxide films are deposited on the bottom of the contact hole, a bonding failure occurs between plug, wiring or the like and the substrate 1S within the contact hole.

According to a second method of this embodiment, the state of light irradiating onto the wafer 1W such as the intensity of the light is changed corresponding to the wafer 1W at least in the rinse processing of the above-described wet processing. When the aforementioned pit or the like occurs, the wet processing is carried out according to the first method and at the same time, while when the oxide films are deposited, the difference in potential between the substrate 1S and chemical fluid or cleaning liquid is controlled by at least adjusting the state of light irradiating onto the wafer 1W such as the light intensity at the time of rinse processing, to suppress the rate of oxidation of silicone on the exposed surface of the substrate 1S or to slow oxidation rate. A specific example for suppressing or preventing the deposition of the oxide films is to perform the wet processing to the wafer 1W in a light shielding condition or under a light so weak as no aforementioned oxide films are deposited. Consequently, the deposition of the oxide films can be suppressed or prevented. More specifically, because deposition of the oxide films on the bottom of the contact hole can be suppressed or prevented, a bonding failure within the contact hole can be suppressed or prevented. Thus, the yield and reliability of the semiconductor device can be improved and cost on the semiconductor device can be reduced in the same way as described above. Further, a wet processing suitable for the wafer 1W is enabled in actual sequential manufacturing steps of the semiconductor device.

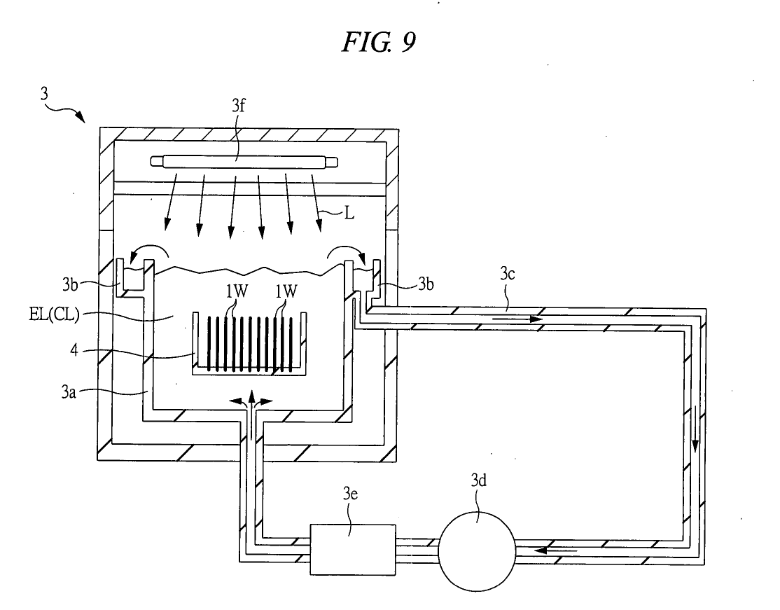

Next, a wet processing apparatus for use in the manufacturing steps of the semiconductor device of this embodiment will be described. FIG. 9 shows an example of the wet etching apparatus (wet processing apparatus) 3 of this embodiment.

This wet etching apparatus 3 is a dipping type wet etching apparatus in which an etching bath composed of, for example, quartz, fluoro plastic or the like is filled with chemical liquid EL or cleaning liquid CL and then, a carrier accommodating plural pieces of the wafers 1W are dipped therein so as to subject the plural pieces of the wafers 1W to etching processing and subsequent rinse processing in batch.

An outer bath 3b is provided on the outer upper periphery of the etching bath 3a of this wet etching apparatus 3. The outer bath 3b is connected to the bottom of the etching bath 3a through a pipe 3c. Then, the chemical liquid EL or cleaning liquid CL overflowing from the etching bath 3a flows into this outer bath 3b and returns into the etching bath 3a from the bottom face of the etching bath 3a through the pipe 3c. A pump 3d, a filter 3e and a temperature adjusting device and the like are provided halfway of the pipe 3c. The aforementioned pump 3d is a circulating functioning section for circulating the aforementioned chemical liquid EL and the cleaning liquid CL. The filter 3e is a filtering functioning section for removing materials from the chemical liquid EL or the cleaning liquid CL.

A light source 3f is provided above the etching bath 3a. This light source 3f irradiates the wafer 1W with light L upon the wet processing, and is comprised of, for example, a fluorescent lamp capable of irradiating the light L including ultraviolet ray. The reason why the ultraviolet ray is included is that the inclusion of the ultraviolet ray facilitates generation of cell reaction at the pn junction of the aforementioned wafer 1W. The light source 3f not only can be turned ON/OFF but also allows the light intensity to be changed. Consequently, the state of irradiated light can be changed for each wafer 1W, so that the wet processing can be executed on each group of the wafers 1W with an optimum light condition.

The ON/OFF control and light intensity control of the light source 3f can be not only manually but also automatically. As the automatic control method of the light source 3f, for example, a following method can be mentioned. That is, according to this method, information of an optimum condition of light projected on the wafer 1W loaded on the wet etching apparatus 3 is stored in the processing data memory section of the wet etching apparatus 3 and the ON/OFF and light intensity of the light source 3f is automatically controlled based thereon. Because this method is available only by changing data, it is easy to correspond to a changing situation.

Because some steps in the manufacturing process of the semiconductor device dislikes light, the light source 3f is sealed so that no light leaks outside. There is no obstacle between the light source 3f and the etching bath 3a in order to project the light L from the light source 3f onto the wafer 1W effectively. Further, it is permissible to provide an inside face of the etching bath 3a with a reflector or the like so as to irradiate the wafer 1W with the light L from the light source 3f effectively.

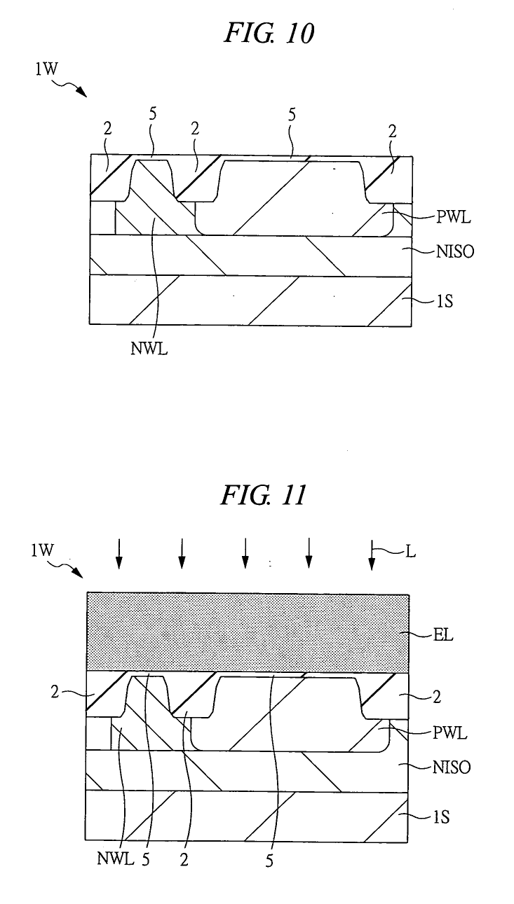

Next, an example of the manufacturing method of the semiconductor device of this embodiment will be described with reference to FIGS. 10-15 showing the sectional views of the principal part of the wafer 1W in the manufacturing step of the semiconductor device. Here, a countermeasure for a case where a pit is generated according to the first method will be described. Because the state of light in the aforementioned wet processing is only different as described above in case of the second method where the oxide films are deposited and the other wet etching processing and rinse processing are the same, description thereof is omitted.

The wafer 1W shown in FIG. 10 is constituted of a thin plate having a substantially circular shape in its plan view which contains, for example, a p-type silicone mono-crystal as the substrate 1S. The n-type embedding region NISO, n-type well PWL and n-type well NWL are formed on the substrate 1S. The groove type separating portion 2 is formed in the main face (device formation face) of the substrate 1S. This separating portion 2 is formed by embedding an insulation film comprised of for example, silicone oxide (SiO₂ or the like) within a groove forming in the thickness direction of the substrate 1S. Further, the insulation film 5 composed of for example, silicone oxide, is formed on the active region of the substrate is surrounded by the separating portion 2.

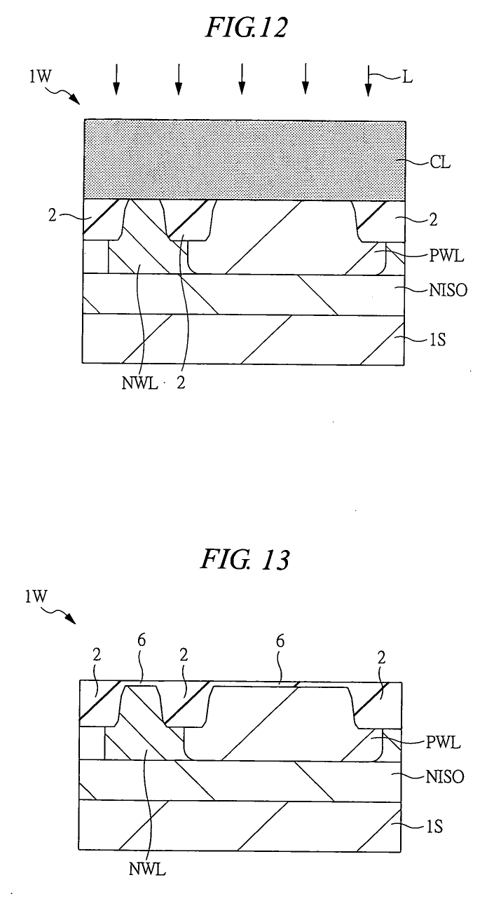

After plural pieces of the wafers 1W are accommodated in the carrier 4, that carrier is transported into the wet etching apparatus 3 and the plural pieces of the wafers 1W are dipped into the chemical liquid EL such as fluoro acid stored in the etching bath 3a, so that mainly the insulation film 5 on the main surface of the wafer 1W is etched. FIG. 11 shows schematically this process. In the etching processing of this embodiment, the light L from the light source 3f is irradiated onto the wafer 1W. That is, a difference of potential between the substrate is and the chemical liquid EL is controlled so that no silicone in the substrate 1S elutes into the chemical liquid EL when the intensity of light irradiated to the wafer 1W is increased or the surface of the substrate is protected by advancing oxidation quickly. Consequently, generation of the pit P or the like in the substrate is can be suppressed or prevented. This etching process can eliminate the aforementioned light irradiation processing depending on the case because a time when the chemical liquid EL make a contact with the surface of the substrate is short and the pit P or the like is generated little. Next, the chemical liquid adhering to the wafer 1W is removed with cleaning liquid such as de-ionized water instead of the chemical liquid EL within the same etching bath 3a. FIG. 12 shows schematically the state of this process. In this process, the cleaning liquid CL makes a direct contact with the exposed surface of the substrate 1S of the wafer 1S. In the cleaning processing of this embodiment, the light L from the light source 3f is projected to the wafer 1W. That is, the difference in potential between the substrate 1S and the cleaning liquid CL is controlled so that no silicone in the substrate 1S elutes into the cleaning liquid CL when the intensity of light irradiated to the wafer 1W is increased or the surface of the substrate 1S is protected by advancing oxidation quickly. Consequently, generation of the pit P or the like in the substrate 1S can be suppressed or prevented. After this wet processing is completed, the carrier 4 is taken out of the wet etching apparatus 3 so as to finish the wet etching processing.

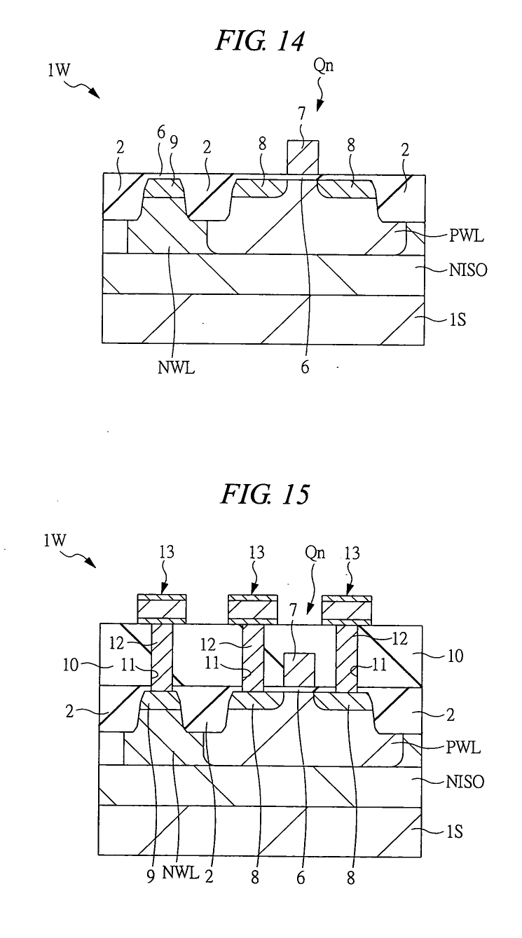

Next, by carrying out thermal oxidation treatment on the wafer 1W, the insulation film 6 composed of, for example, silicone oxide is formed on the exposed surface of the wafer 1W as shown in FIG. 13. The insulation film 6 in the MIS formation region acts as a gate insulation film. Subsequently, after conductive films comprised of, for example, polycrystal silicone having a low resistance are deposited on the main surface of the wafer 1W according to the chemical vapor deposition (CVD) method or the like as shown in FIG. 14, that conductive film is patterned with ordinary photo-lithography technology and dry etching technology so as to form a gate electrode 7 on the insulation film 6 in the MIS formation region. After that, n⁺type semiconductor regions 8, 9 are formed by introducing, for example, phosphorus (P) or arsenic (As) to the substrate 1S with ion implantation method or the like. The n⁺type semiconductor region 8 in the MIS formation region is a semiconductor region for the MIS source and drain. The n⁺type semiconductor region 9 is a drawn region of the n⁺type embedding region NISO. In this way, nMIS Qn is formed on the main surface of the wafer 1W.

Subsequently, after the insulation films 10 comprised of, for example, silicone oxide are deposited on the main surface of the wafer 1W with the CVD method or the like as shown in FIG. 15, contact holes 11 are formed in the insulation film 10 so that part of the substrate 1S is exposed with ordinary photo-lithography technology and dry etching technology. After, for example, titanium nitride (TiN) and tungsten (W) are deposited in order from the bottom on the main surface of the wafer 1W, they are polished with the chemical mechanical polishing (CMP) method so that they are left only within the contact hole 11, so as to form a plug 12 in the contact hole 11. After that, a first wiring layer 13 comprised of mainly aluminum or aluminum alloy is formed on the insulation film 10 through ordinary wiring formation process. The production of the semiconductor device is completed through normal production steps.

In the foregoing, the invention made by the inventors of the present invention has been concretely described based on the embodiment. However, it is needless to say that the present invention is not limited to the foregoing embodiment and various modifications and alterations can be made within the scope of the present invention.

Although the fluorescent lamp is used as a light source of the above-described embodiments, the present invention is not restricted to this example and this lighting means may be changed as long as it produces electromagnetic wave which generates a cell reaction in the pn junction of the wafer and allows adjustment of its electromotive force. For example, it is permissible to use a mercury-vapor lamp or the like.

Although mainly the case for changing the intensity of light has been described in the above embodiments, the present invention is not restricted to this example but the frequency of light may be changed to an optimum one for preventing generation of the aforementioned pit and oxide film corresponding to the pn junction in the wafer.

Although the above-described embodiment is applied to the batch type wet etching apparatus, the present invention is not restricted to this example. For example, the embodiments can be applied to a sheet-type wet etching apparatus which adopts spin type wet etching processing in which with a semiconductor wafer fixed on a supporting base rotating, the chemical liquid is sprayed to the etching processing face of that semiconductor wafer.

Although according to the above embodiment, the separating portion is of groove type, the present invention is not restricted to this example. Because the same problem occurs even if the separating portion is formed with field insulation film formed with for example, local oxidization of silicone (LOCOS) method, the above-described embodiment can be applied to such a case.

Although a case where the present invention is applied to manufacturing method of a semiconductor device having only the MIS, which is a related technical field of the invention, has been stated in the above description, the present invention is not restricted to this example. The present invention may be applied to a semiconductor device having such a memory device as dynamic random access memory (DRAM), static random access memory (SRAM) and electric erasable programmable read only memory (EEPROM) and a semiconductor device having a bipolar transistor as its substrate and other semiconductor devices.

The typical effect which the present invention achieves is as follows.

That is, according to the present invention, formation of a dissolution region of composition atoms such as the pit in the semiconductor wafer can be suppressed or prevented by changing the state of light irradiated to the semiconductor wafer at the time of the wet processing corresponding to a semiconductor wafer subjected to the wet processing.

What is claimed is:

1. A wet processing apparatus, comprising: a processing section for performing wet processing of wet etching processing and rinse processing onto a semiconductor wafer; and a light source for adjusting the state of light irradiating to the semiconductor wafer at the time of the wet processing.

2. The wet processing apparatus according to claim 1, wherein light from the light source contains ultraviolet ray.

3. A wet processing method, comprising a wet processing step of rinsing a semiconductor wafer after wet etching processing is performed onto the semiconductor wafer, wherein the state of light irradiating to the semiconductor wafer is changed corresponding to a semiconductor wafer subjected to the wet processing at least in the rinse processing of the wet processing step.

4. The wet processing method according to claim 3, wherein the wet processing selects any one of a step of performing the wet processing in light shielding condition corresponding to the semiconductor wafer and a step of performing the wet processing with-light irradiating.

5. The wet processing method according to claim 3, wherein the wet etching processing is a step of removing oxide film from the surface of the semiconductor wafer with etching fluid containing fluoro acid.

6. The wet processing method according to claim 3, wherein the semiconductor wafer subjected to the wet processing has a pn junction.

7. A manufacturing method of a semiconductor device, comprising a wet processing step of rinsing a semiconductor wafer after wet etching processing is performed onto the semiconductor wafer, wherein the state of light irradiating to the semiconductor wafer is changed corresponding to a semiconductor wafer subjected to the wet processing at least in the rinse processing of the wet processing step.

8. The manufacturing method of the semiconductor device according to claim 7, wherein the wet processing selects any one of a step of performing the wet processing in light shielding condition corresponding to the semiconductor wafer and a step of performing the wet processing with light irradiating.

9. The manufacturing method of the semiconductor device according to claim 7, wherein the wet etching processing is a step for removing oxide film from the surface of the semiconductor wafer with etching fluid containing fluoro acid, and the manufacturing method further comprising a step of forming an insulation film on the surface of the semiconductor wafer after the wet processing is performed.
